(19) United States
(12) Patent Application Publication
(10) Pub. No.: US 2002/0190726 A1
(43) Pub. Date: Dec. 19, 2002

(54) SYSTEM AND METHED FOR REMOTELY MONITORING AN INTERFACE BETWEEN DISSIMILAR MATERIALS

(75) Inventor: Norbert E. Yankielun, Lebanon, NH (US)

Correspondence Address: U.S. Army Corps of Engineers, Humphreys Engineer Center, 7701 Telegraph Road, ATTN: CEHEC - OC ( Kingman Building), Alexandria, VA, 22315-3860, US

(73) Assignee: Secretary of the Army

(21) Appl. No.: 09/879,001

(22) Filed: Jun. 13, 2001

(51) Int. Cl. G01R 27/32; G01R 27/04

(52) U.S. Cl. 324/644

(57) ABSTRACT

A scour sensor assembly includes a pair of substantially parallel electrically conductive leads for disposition in a water/sediment interface such that a first portion of a length of each lead is disposed in the sediment below the interface and a second portion of the length of each lead is disposed in the water above the interface. A pulse propagation electronics assembly is fixed at first ends of the pair of leads and is adapted to send periodic electromagnetic pulses of positive polarity through the leads toward second ends of the leads and to receive reflected pulses from the interface and the lead second ends. The electronics assembly is adapted to detect a pulse reflected from the interface and to thereupon send a new pulse, the reflected pulses received from the second ends of the leads and from the interface being of opposite polarity.

### BACKGROUND OF THE INVENTION

1. Field of the Invention

The invention relates to detection and monitoring devices and is directed more particularly to an assembly for detecting and monitoring the presence of scour in underwater beds, such as river beds, navigational channels, and the like.

2. Description of the Prior Art

Scour is a severe problem that results in millions of dollars of damage to infrastructure and substantial loss of life annually. Scour occurs during times of high tides, hurricanes, rapid river flow, and icing conditions, when sediment, including rocks, gravel, sand, and silt, are transported by currents, undermining bridge and pier foundations, submarine utility cables, and pipelines, and filling in navigational channels. Scour is dynamic; ablation and deposition can occur during the same high-energy hydrodynamic event. The net effect of scour has not been easily predicted, nor readily monitored, in real-time heretofore.

Bridge scour monitoring technologies are known. In U.S. Pat. No. 5,784,338, issued Jul. 1, 1998 to Norbert E. Yankielun et al, an instrument called a “time domain reflectomer”(TDR) is directly connected to a parallel transmission line consisting of a pair of robust, specially fabricated non-corroding rods or wires (hereinafter “leads”). The principle of TDR is generally known, described in the technical literature, and applied to numerous measurements and testing applications. The technique was applied to scour detection and monitoring in the aforesaid '338 patent, which is incorporated herein by reference. TDR operates by generating an electromagnetic pulse, or a fast rise time step, and coupling it to a transmission line. The pulse travels down the transmission line at a fixed and calculable velocity, a function of the speed of light and the electrical and physical characteristics of the transmission line. The pulse propagates down the transmission line until the end of the line is reached, and is then reflected back toward the source. The time in seconds that it takes for the pulse to propagate down and back the length of the transmission line is called the “round trip travel time” and is calculated as described in the '338 patent.

For a two wire parallel transmission line, changes in the dielectric media in the immediate surrounding volume cause a change in the round trip travel time. Further, at any boundary condition along the transmission line (e.g., air/water and water/sediment), a dielectric discontinuity exists. As a pulse traveling down the transmission line from the TDR source encounters these boundary conditions, a portion of pulse energy is reflected back to the source from the boundary. A portion of the pulse energy continues to propagate through the boundary until another boundary or the end of the cable, causes all or part of the remaining pulse energy to return along the transmission line toward the source. Measuring the time of flight of the two reflected pulses, and knowing the dielectric medium through which the pulse is traveling, permits calculation of the physical distance from the TDR source to the dielectric interface boundary, or boundaries, encountered.

Freshwater has a relatively high dielectric constant and dry sedimentary materials (e.g.: soil, gravel and stone) have a relatively low dielectric constant. Wet sediment has a dielectric constant that is a mixture of the constants of water and dry soil. The dielectric constant of this mixture will vary, depending upon the local sedimentary material constituency. However, in all cases of bulk dielectric, the bulk index of refraction of the mixture will be less than that of liquid water alone and significantly greater than that of the dry sedimentary materials. Some sediment materials, particularly clay-based sediments, can be extremely “lossy”. This lossy behavior of the soil is exhibited by a severe attenuation of an electromagnetic pulse as it propagates along a transmission line surrounded by such materials. The pulse, when launched from a TDR, dissipates as it travels along the transmission line. Sufficient dissipation reduces the reflected pulse energy below a detectable level.

For lossy consolidated soils, such as clay, the electromagnetic signal is greatly attenuated as it propagates along the imbedded transmission line leads. Levels of signal attenuation can be as much as 10's of decibels per meter. This results in little or no reflected signal returned to the instrument over the length of the leads buried in the lossy media. If the sensor source is imbedded in lossy media, along with a portion of the sensor leads; the media can absorb all, or nearly all of the pulse energy, such that little or no reflected signal is returned. If a pulse is propagating along a transmission line imbedded in a non- or minimally-lossy material and a boundary with some extremely lossy material is encountered, a reflection will occur at the interface boundary, similarly to that that would occur for a boundary between two non-lossy materials. The magnitude of the reflection will be proportional to the reflection coefficient of the two materials at the interface.

When one or both of the reflected signals from the interface and the distal ends of the leads are severely weakened by attenuation, the TDR electronics can experience difficulty in discerning one from the other and in providing consistently accurate readings.

Accordingly, there is a need for a reflectometry system which provides distinct and useful signals reflected from a boundary layer on a continuing basis so as to provide reliable monitoring of scour conditions in real-time.

### SUMMARY OF THE INVENTION

An object of the invention is, then, to provide a reflectometry system for operation in soil, which system provides readily discernible signals reflected from a boundary layer and a distal end of a sensor, which signals are sufficiently robust for use in determining the position of the boundary layer on a real-time basis and thereby permit continuous monitoring of the boundary layer position.

With the above and other objects in view, as will hereinafter appear, a feature of the invention is the provision of a scour sensor assembly comprising a pair of substantially parallel electrically conductive leads for disposition in a water/sediment interface, such that a first portion of a length of each lead is disposed in the sediment below the interface and a second portion of the length of each lead is disposed in the water above the interface, a pulse propagation electronics assembly fixed at first ends of the pair of leads and adapted to send periodic electromagnetic pulses of positive polarity through the leads toward second ends of the leads and to receive reflected pulses from the interface and distal ends of the leads, the electronics assembly being adapted to detect the reflected pulses from the interface and to thereupon send a new pulse, the reflected pulses received from the second ends of the leads and from the interface being of opposite polarity.

The above and other features of the invention, including various novel details of construction and combinations of parts, will now be more particularly described with reference to the accompanying drawings and pointed out in the claims. It will be understood that the particular devices embodying the invention are shown by way of illustration only and not as limitations of the invention. The principles and features of this invention may be employed in various and numerous embodiments without departing from the scope of the invention.

### BRIEF DESCRIPTION OF THE DRAWINGS

Reference is made to the accompanying drawings in which are shown illustrative embodiments of the invention, from which its novel features and advantages will be apparent.

In the drawings:

FIG. 1 is a diagrammatic illustration of one form of scour sensor assembly illustrative of an embodiment of the invention;

FIG. 2 is a graph depicting pulse polarities generated by the assembly of FIG. 1;

FIG. 3 is a diagrammatic illustration of another form of scour sensor assembly illustrative of an alternative embodiment of the invention;

FIG. 4 is a graph depicting pulse polarities generated by the assembly of FIG. 3; and

FIG. 5 is a schematic diagram of the scour probe assembly and particularly the electronic components thereof.

### DESCRIPTION OF THE PREFERRED EMBODIMENTS

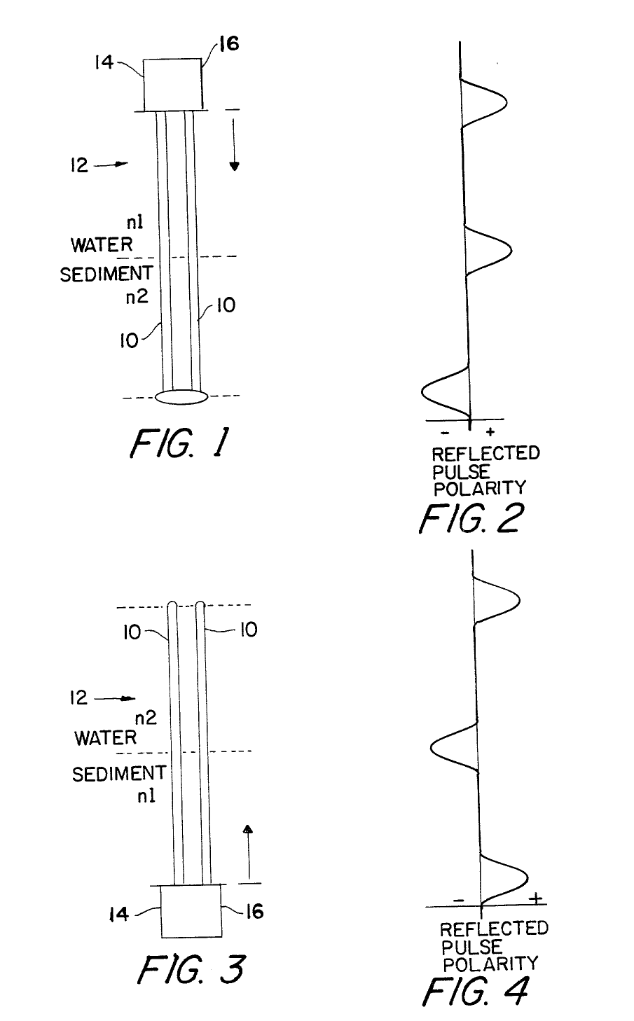

Referring to FIG. 1, it will be seen that an illustrative embodiment of the scour sensor assembly includes a pair of substantially parallel electrically conductive leads 10 forming a reflectometer sensor 12 (FIGS. 1 and 2). The leads 10 may comprise wires or rods and typically are about 3-6 feet long. The diameter and spacing of the leads 10 preferably are determined so as to ensure impedance match between the leads 10 and surrounding sediments. The diameter of the leads usually is about 1/16 to ⅛ inch. The two leads 10 may be short-circuited (FIG. 1) or open circuited (FIG. 3) at the distal extremity thereof. An open or short circuit does not substantially affect the operation of the probe, except to determine the polarity of the reflected pulse. An open-circuited pair of sensor leads (FIG. 3) reflects the pulse from the distal end with the same polarity as transmitted (FIG. 4). A short-circuited pair of sensor leads (FIG. 1) reflects the pulse from the distal end with the opposite polarity from that transmitted.

The sensor probe assembly still further includes an electronics package 14 comprising a time domain reflectometer (TDR) 16 affixed to ends of the leads 10. A cable (not shown) provides DC power for the sensor electronics 14.

The magnitude of the reflection from the interface is proportional to the reflection coefficient, p, based on the two materials at the interface, where

p−(n₁−nₜ)/(n₁+nₜ)

and where

n₁=refractive index of the material at the boundary, and nearer the sensor electronics, and

n₂=refractive index of material at the boundary, and more removed from the sensor electronics.

Given that a positive polarity pulse is initially generated, the values of n₁ and n₂ determine the polarity of the interface reflected pulse. If n₁ is greater than n₂(FIG. 1) a positive polarity interface reflection pulse will result. If n₁ is less than n₂(FIG. 3) a negative polarity reflection pulse will result. In the configuration of FIG. 1 the electronics 14 are located on top of the sensor leads 10 and the far end of the sensor is buried deep in the sediments below. FIG. 1 illustrates a preferred embodiment because the transmitted pulse travels from the top down, propagating through the less lossy medium of water until encountering the water/sediment boundary and being reflected back towards the source 16. The sensor assembly can be configured such that the reflected pulse at the distal end of the sensor leads 10 is of a negative polarity and the reflected pulse at the sediment/water boundary is of a positive polarity, as illustrated in FIG. 2. The combination of location of the electronics 14 (top- vs. bottom-mounted) and the use of an open-circuited or short-circuited distal end of the sensor 12 can be used to permit selection of the relative polarities of the reflected pulse.

FIG. 3 illustrates an alternative embodiment of the sensor 12 wherein the electronics 14 are located on the bottom of the sensor leads 10, buried in the bottom sediments. Here, the water/sediment reflection pulse has a different polarity from that of either the generated pulse at the proximal end of the probe or the reflected pulse at distal end of the sensor (FIG. 4). This embodiment, while providing the desired function, is less desirable than that shown in FIG. 1. In FIG. 3, the embodiment illustrated in the transmitted pulse must travel through potentially lossy sediment before encountering the sediment/water boundary, potentially resulting in an attenuated reflection pulse.

By using the configurations of FIG. 1 (electronics on top and short circuited distal end of the leads) or that of FIG. 3 (electronics on the bottom and an open-circuited distal lead ends), the water/sediment boundary (or sediment/water boundary, relative to pulse propagation direction) reflection is of opposite polarity to the reflection pulses at the distal end. By having the water/sediment boundary reflection pulse of opposite polarity to reflections from the distal ends in the system, it is relatively simple to use this pulse as a unique trigger for operation of this system, and to electronically identify the two reflected pulses and effect computations relative thereto.

The water/sediment interface results in a positive polarity reflected pulse when propagation transitions from water (higher n) into sediment (lower n), as illustrated in FIG. 1. From basic transmission line theory, when the distal end of the probe is shorted, as in FIG. 1, the reflection pulse will always have a negative polarity with respect to the originally generated pulse. FIG. 1 is illustrative of the preferred embodiment inasmuch as the sensor functions well in either lossy or non-lossy sediments. With this configuration, the water/sediment boundary reflection pulse can be uniquely identified electronically, and used to determine current sediment depth and monitor changes.

In the probe configuration of FIG. 3, the electronics 14 are located at the bottom of the sensor 12, buried in the sediments, and the distal end of the sensor leads extend upwardly across the sediment/water boundary. While this configuration affords the sensor electronics 14 greater protection from the forces of the currents and from impacts with current carried debris, it does not function as well as the embodiment of FIG. 1 in consolidated sediments, as explained earlier. The reflected pulse resulting at the distal end of the sensor has an opposite polarity from the pulse refection at the sediment/water boundary. When the distal end of the sensor is open-circuited (FIG. 3), the distal end reflection pulse exhibits the same polarity (here assumed positive) as the originally generated pulse. The sediment/water interface results in a negative polarity interface reflected pulse when propagation transitions from sediment (lower n) into water (higher n).

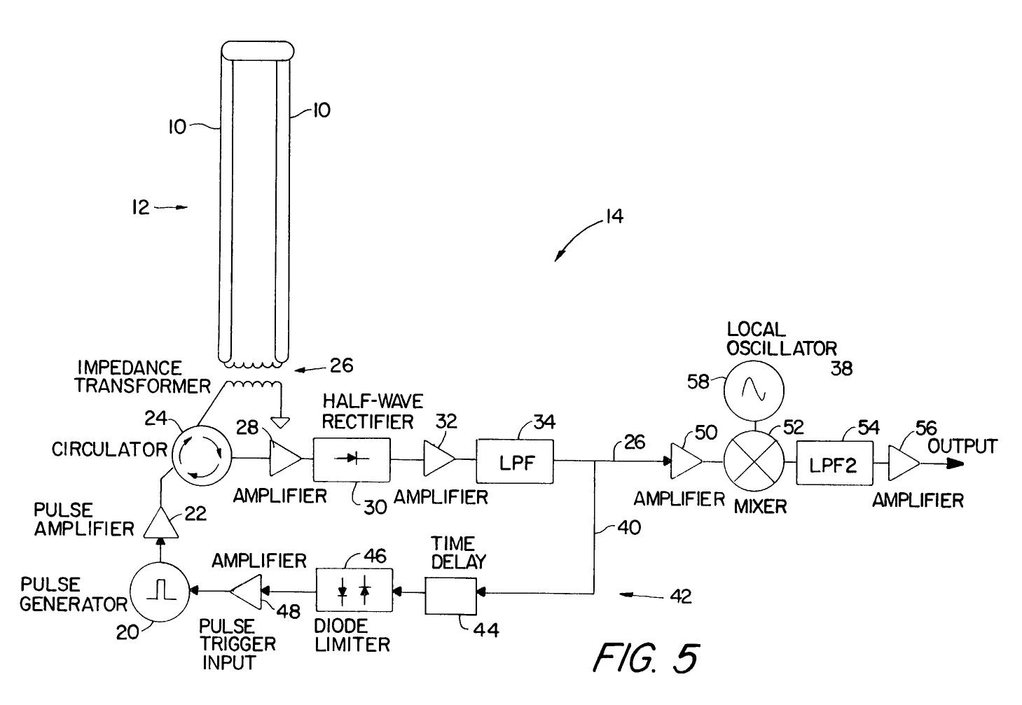

A generalized block diagram for the implementation of the system is shown in FIG. 5. A retriggerable pulse generator 20 is used to generate a narrow pulse, which is amplified (if needed), as by a pulse amplifier 22, to an appropriate level. The pulse travels into a circulator 24, or alternatively, into a “T” junction (not shown). The pulse is routed through an impedance transformer 26 that matches the impedance of the internal electronics of the system to the impedance of the sensor leads 10 surrounded by a dielectric material. In the intended application of this system, the surrounding dielectric material is water, sediment or saturated sediment. In some cases, the impedance transformer 26 can be omitted if the physical dimensions of the sensor (e.g., lead spacing and diameters) are chosen to facilitate a good impedance match. The impedance transformer-coupled pulse propagates along the sensor leads 10, as explained earlier herein. The reflected pulse, from either the distal end of the sensor or an intermediate boundary, returns along the leads 10, back through the impedance transformer 26, and through an amplifier 28. Here the reflected pulse is passed through a half-wave rectifier 30 with polarity chosen to pass the sediment/water interface pulses and block the distally reflected pulse. The pulse is passed through a gain-providing inverting amplifier 32 and a low pass filter (LPF) 34 to remove the DC component from the pulse.

The pulse then has two paths. A first path 36 leads to output circuitry 38, and the second path 40, to a feedback circuit 42. The feedback circuit 42 may include an optional time delay, 44, which can be used to set a minimum repetition rate for pulse cycling. Once through the delay 44, the pulse is signal conditioned by a diode limiter 46 and amplifier 48 that converts the rounded pulse into a flat-topped pulse with a steep rise-time. This conditioned pulse is used to retrigger the pulse generator 20 to produce a new narrow width pulse and start the process over. This cyclic process produces a train of pulses at the output of LPF. The repetition rate (frequency) of the pulse train is proportional to the round-trip travel time of the pulse as it propagates down the sensor leads 10 and is reflected back from the sediment/water interface boundary. The repetition rate can be related to the depth of scour, as earlier described for the traditional TDR.

The first output path 36 of the pulse, once passed through LPF 34, is into an amplifier 50, mixer 52, a second low pass filter 54 and another amplifier 56. The purpose of the output circuitry 38 is to down-convert the repetition rate of the pulse train to a frequency that can be conveniently transmitted via cable, narrowband radio telemetry, or other transmission means. The frequency of a local oscillator 58 is selected in respect to the pulse repetition frequency so that the frequency difference product of the mixer 52 lies within the bandwith desired for transmission.

A cable-based TDR system is primarily intended for long-term or permanent monitoring situations where an umbilical, low-loss coaxial cable (not shown) can be easily and more permanently installed. This usually implies a physically short distance, typically a few hundred feet, between the leads and the TDR system. An implementation using batteries and a wireless radio or submerged acoustic telemetry link, is intended for shorter-term applications where the sensor can be retrieved, perhaps annually, for refurbishing and replacement of batteries.

In practical installation, the scour sensor system is buried in river bottom sediments and anchored at a point below the maximum expected depth of scour (FIG. 1). For low-loss sediments, the sensor can be installed with the electronics deeply buried in the sediments (FIG. 3). Here the transmitted pulse travels from the system electronics package through the sediments and produces reflections from both the water/sediment boundary and the physical end of the sensor. Where the sediments are composed of consolidated soils, such as clay, where the electrical losses can be severe, the sensor preferably is configured with the electronics at the top of the sensor leads (FIG. 1). Here, the pulse travels downward from the electronics package and produces a reflection at the water sediment boundary.

Primarily, the sensor assembly is designed for installation by “air jetting” or “hydro jetting”. Alternatively, the sensor can be installed in softer sediments by being “pile driven” or hydraulically forced into the sediments. The top of the sensor is “surveyed in” relative to a local survey benchmark.

Following installation, an initial reference reading is made of the sensor signal response, and the round trip travel time for a pulse propagating along each sensor lead is calculated and stored in an associated computer. Subsequent signal responses and round-trip propagation times are frequently and automatically (or manually, if desired) acquired, calculated, and compared with the original reference data set. A real-time computer algorithm may be used to compare the reference round-trip travel time with subsequent values, and trigger an alarm when a significant change is observed in the sensor signal response or a threshold difference in round trip travel time is reached. Depending on the desired implementation, sensor output signals can be multiplexed to monitor a sensor array consisting of numerous sensor assemblies installed in close proximity to a structure or sediment field of interest.

It is to be understood that the present invention is by no means limited to the particular constructions herein disclosed and/or shown in the drawings, but also comprises any modification or equivalent within the scope of the claims.

What is claimed is:

1. A scour sensor assembly comprising:
a pair of substantially parallel electrically conductive leads for disposition in a water/sediment interface such that a first portion of a length of each lead is disposed in sediment below the interface and a second portion of the length of each lead is disposed in water above the interface;
a pulse propagation electronics assembly fixed at first ends of said pair of leads and adapted to send periodic electromagnetic pulses of positive polarity through said leads toward second ends of said leads and to receive reflected pulses, said electronics assembly being adapted to detect a pulse reflected from the interface and to thereupon send a new pulse, the reflected pulses received from the second ends of the leads and from the interface being of opposite polarity.

2. The scour sensor assembly in accordance with claim 1 wherein said electronics assembly includes a computer adapted to compute travel times of (1) the pulses reflected from the second ends of the leads, and (2) the pulses reflected from the water/sediment interface and therefrom determine depth of the interface on a continuing basis.

3. The scour sensor assembly in accordance with claim 2 wherein said pulse propagation electronics assembly comprises a reflectometer in communication with said leads.

4. The scour sensor assembly in accordance with claim 3 wherein said reflectometer comprises a time domain reflectometer.

5. The sensor assembly in accordance with claim 2 wherein said electronics assembly is disposed at an upper end of said leads, and distal ends of said leads is short-circuited.

6. The sensor assembly in accordance with claim 2 wherein said electronics assembly is disposed at a bottom end of said leads, and distal ends of said leads is open.

7. The sensor assembly in accordance with claim 5 wherein said electronic assembly is disposed above the interface and the distal ends of said leads is disposed within the sediment.

8. The sensor assembly in accordance with claim 6 wherein said electronic assembly is buried in the sediment and the distal ends of said leads are disposed in the water.

9. The sensor assembly in accordance with claim 2 wherein the assembly comprises an impedance transformer interconnecting said leads and said electronic assembly.

10. The sensor assembly in accordance with claim 9 wherein the electronic assembly includes a half-wave rectifier in communication with said impedance transformer and adapted to pass interface reflected pulses and block distally reflected probes, and a pulse generator in communication with the half-wave rectifier and operative to initiate a new pulse.
